(19) United States
(12) Patent Application Publication
(10) Pub. No.: US 2026/0095195 A1
(43) Pub. Date: Apr. 2, 2026

(54) COEFFICIENT FEATHERING USING DELTA SIGMA MODULATION

(71) Applicant: SKYWORKS SOLUTIONS, INC., Irvine, CA (US)

(72) Inventors: David Lamb, Portland, OR (US); Arman Samimi-dehkordi, Mountain View, CA (US)

(21) Appl. No.: 19/339,471

(22) Filed: Sep. 25, 2025

Related U.S. Application Data
(60) Provisional application No. 63/699,918, filed on Sep. 27, 2024.

(51) Int. Cl. H03M 7/32; H03K 5/14

(52) U.S. Cl. CPC H03M 7/3031; H03K 5/14; H03M 7/3028

(57) ABSTRACT

A system for determining one or more coefficients of a filter is presented. The system includes a modulated ramp generator including a ramp generator, a delta-sigma modulator coupled to the ramp generator and configured to generate a control signal, and a control output coupled to the delta-sigma modulator and configured to receive the control signal; and a filter coupled to the control output and configured to receive the control signal from the control output, the filter including one or more configurable coefficients, values of the configurable coefficients being selected by the control signal, an input for receiving a filterable signal, and an output for providing a filtered signal.

### CROSS-REFERENCE TO RELATED APPLICATIONS

This application claims priority to U.S. Provisional Patent Application No. 63/699,918, titled COEFFICIENT FEATHERING USING DELTA SIGMA MODULATION, filed on Sep. 27, 2024, and hereby incorporated by reference in its entirety for all purposes.

### BACKGROUND

### 1. Field of the Disclosure

At least one example in accordance with the present disclosure relates generally to controlling the response of digital filter systems.

### 2. Discussion of Related Art

Digital filters are widely used in electronics. Many digital filters have adjustable responses so that the behavior of the digital filter may be dynamically altered during operation of the electronic system.

### SUMMARY

According to at least one aspect of the present disclosure a system for determining one or more coefficients of a filter is presented, comprising: a modulated ramp generator including a ramp generator, a delta-sigma modulator coupled to the ramp generator and configured to generate a control signal, and a control output coupled to the delta-sigma modulator and configured to receive the control signal; and a filter coupled to the control output and configured to receive the control signal from the control output, the filter including one or more configurable coefficients, values of the configurable coefficients being selected by the control signal, an input for receiving a filterable signal, and an output for providing a filtered signal.

In some examples, the delta-sigma modulator further includes a first summing node having an input coupled to an output of the ramp generator; a quantizer having a quantizer input coupled to an output of first summing node and a quantizer output coupled to the control output; a second summing node coupled to an output of the first summing node and to the quantizer output; and a delay line coupled to an output of the second summing node and an input of the first summing node. In some examples, the first summing node is configured to add an output signal of the delay line to an output signal of the ramp generator, and to provide a resulting summed signal to the second summing node and the quantizer. In some examples, the second summing node is configured to add an output signal of the first summing node to an output signal of the quantizer and to provide a resulting summed signal to the delay line. In some examples, the quantizer is a one-bit quantizer. In some examples, the quantizer is configured to provide a control signal to the control output, the control signal being based on an output signal of the first summing node. In some examples, the filter includes a plurality of multipliers and a plurality of multiplexers. In some examples, each multiplexer is configured to receive the control signal. In some examples, each respective multiplexer of the plurality of multiplexers is configured to selectively provide one of a first coefficient and a second coefficient to a respective multiplier of the plurality of multipliers based on the control signal. In some examples, the first coefficient corresponds to a low voltage and the second coefficient corresponds to a high voltage. In some examples, a rate of occurrence over a period of time of the first coefficient decreases over the period of time and a rate of occurrence over a period of time of the second coefficient increases over the period of time. In some examples, before the period of time, the rate of occurrence of the first coefficient is 100%, and after the first period of time, the rate of occurrence of the first coefficient is 0%. In some examples, before the period of time, the rate of occurrence of the first coefficient is 0%, and after the first period of time, the rate of occurrence of the first coefficient is 100%. In some examples, before the period of time, the rate of occurrence of the second coefficient is 100%, and after the first period of time, the rate of occurrence of the second coefficient is 0%. In some examples, before the period of time, the rate of occurrence of the second coefficient is 0%, and after the first period of time, the rate of occurrence of the second coefficient is 100%. In some examples, the filter includes a multiplier and a multiplexer, the multiplexer being configured to selectively provide one of a first coefficient and a second coefficient as a selected coefficient to the multiplier based on the control signal, wherein the multiplier multiplies the selected coefficient with a target signal and generates a multiplied signal based on the selected signal and the target signal. In some examples, the filter includes one or more delay lines. In some examples, the filter includes one or more summing nodes. In some examples, the delta-sigma modulator is configured to oversample an output signal of the ramp generator. In some examples, the configurable coefficients are either a 0 or a 1.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a digital filter according to an example;

FIG. 2 illustrates a modulated ramp generator according to an example; and

FIG. 3 illustrates a set of graphs corresponding to coefficients being provided to a filter according to an example.

### DETAILED DESCRIPTION

In electronic systems, digital filters are commonly used for a wide variety of tasks, including being used as adaptive filters in audio equalizers, active noise cancellation systems, phase-locked loops, and so forth. When on-the-fly adjustments to the characteristics (such as the frequency response or simply “response”) of the filter are required, the coefficients provided to the digital filter may be changed. However, changes to the characteristics of the filter can cause undesirable changes to the signal being filtered.

For example, the coefficients of the filter may all be changed at once (e.g., on the same clock cycle). However, this may cause a sudden change in the response of the filter which can cause artifacts in the signal being filtered. As an illustrative case, in audio applications, a sudden change in the response of a digital filter being used to filter an audio signal may result in an audible and undesirable pop or click noise or similar artifact.

In other examples, the coefficients may be changed in an interpolative process, where the coefficients are changed gradually to the target value over a period of time (i.e. a linear ramp). For example, the coefficients could have initial values, and a desired set of target values, and the initial values could be changed to the target values by slightly changing the initial value every clock cycle over a given number of clock cycles, until the target values are reached. This method may result in relatively fewer and/or less intense artifacts compared to changing the coefficients from the initial value to the target value all at once (e.g., in a single clock cycle). However, this method generally requires more hardware compared to the above-described method.

More hardware may be required because the coefficients used during the interpolative process (e.g., the coefficients used each clock cycle during the transition from initial value to target value) may require a certain degree of precision, which may, in some examples, be expressed in bits. For example, an 8-bit value may not be able to express the coefficients properly, for instance, because two values are too close together and the resolution of an 8-bit number may be too low to differentiate the two values. In other cases, the values may not have a sufficient number of significant figures to properly capture the desired coefficient, leading to rounding errors and the like that affect the performance of the digital filter. As a result, depending on the length of time provided for the transition from initial to target coefficient values, and the desired resolution of the coefficients, larger and larger registers may be required to implement the filter (e.g., a 32-bit register may be needed to hold a coefficient instead of an 8-bit register). In ASICs, the power and area of the multipliers of the filter will grow with the bit width of the coefficients, leading to inefficient designs.

Thus, there is a tradeoff between filter performance and the amount of hardware required to have a desired level of performance.

According to aspects of this disclosure, systems and methods for having excellent filter performance are provided while simultaneously minimizing the hardware cost of the associated digital filter system. In the systems and methods disclosed herein, interpolation is not required. Instead, two coefficient values (the initial and the target values) are used. During a period of time, the filter coefficients are switched between the initial and target value such that the amount of time the coefficients are equal to the initial value gradually decreases over the transition period, until only the target value is used (once the transition is complete). This may be thought of as an oscillation between the initial and target value, where the frequency of changes gradually increases and then decreases over the course of the transition period. The pattern of switching between the initial and target coefficient (the “transition pattern”) may be a predetermined pattern, and/or may be non-random and/or non-pseudo-random. In some examples, all coefficients may be changed simultaneously, though in other examples, coefficients may be transitioned from initial to target values at different times and/or independently of one another (and/or according to different transition patterns).

The systems and methods disclosed herein may be applied to any filter topology, and require very little additional hardware beyond the hardware required to implement the desired filter topology. Thus, any order of filter and any type of filter (IIR, FIR, low-pass, band-pass, high-pass, and so on) may benefit from the systems and methods disclosed herein.

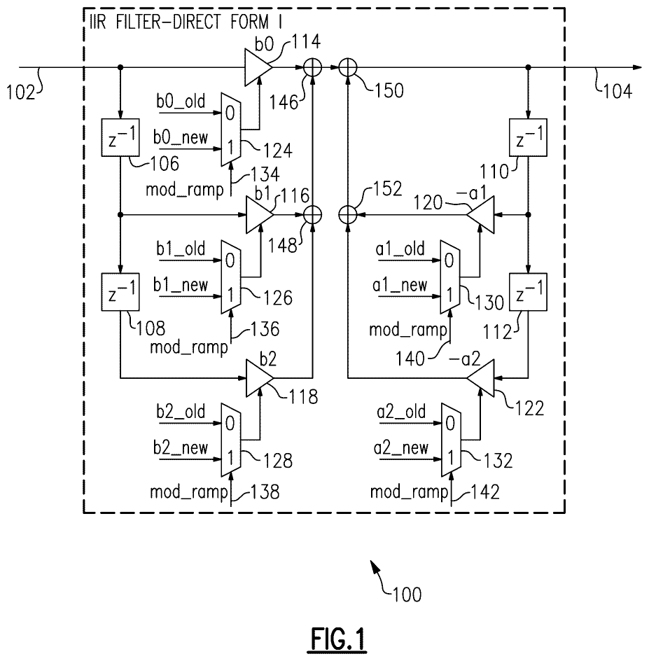

FIG. 1 illustrates a digital filter 100 (“filter 100”) according to an example. The filter 100 includes an input 102, an output 104, a first delay 106, a second delay 108, a third delay 110, a fourth delay 112, a first multiplier 114, a second multiplier 116, a third multiplier 118, a fourth multiplier 120, a fifth multiplier 122, a first multiplexer (MUX) 124, a second MUX 126, a third MUX 128, a fourth MUX 130, a fifth MUX 132, a first select input 134, a second select input 136, a third select input 138, a fourth select input 140, a fifth select input 142, a first adder (“summing node”) 146, a second summing node 148, a third summing node 150, and a fourth summing node 152.

The input 102 is coupled to the first multiplier 114 and to the first delay 106. The first delay 106 is coupled to the second multiplier 116 and the second delay 108. The second delay 108 is coupled to the third multiplier 118. The third multiplier 118 and second multiplier 116 are coupled to the second summing node 148. The second summing node 148 and the first multiplier 114 are coupled to the first summing node 146. The first summing node 146 is coupled to the third summing node 150. The third summing node 150 is coupled to the output 104 and the third delay 110. The output 104 is coupled to the third delay 110. The third delay 110 is coupled to the fourth multiplier 120 and the fourth delay 112. The fourth delay 112 is coupled to the fifth multiplier 122. The fourth multiplier 120 and fifth multiplier 122 are coupled to the fourth summing node 152. The fourth summing node 152 is coupled to the third summing node 150.

Additionally, each multiplier is associated with a respective MUX. The first MUX 124 is coupled to the first multiplier 114 and configured to receive a select signal from the first select input 134. The second MUX 126 is coupled to the second multiplier 116 and configured to receive a select signal from the second select input 136. The third MUX 128 is coupled to the third multiplier 118 and configured to receive a select signal from the third select input 138. The fourth MUX 130 is coupled to the fourth multiplier 120 and configured to receive a select signal from the fourth select input 140. The fifth MUX 142 is coupled to the fifth multiplier 122 and configured to receive a select signal from the fifth select input 142.

Each MUX 124-132 is configured to provide a respective coefficient to the respective multiplier 114-122 to which the MUX is coupled. For example, as illustrated, each MUX 124-132 has two inputs for coefficients and a select input for a select signal. The select signal may, for example, be a first value or a second value (such as a first voltage or a second voltage, the two voltages may correspond to a logical “high” and “low” value). When the select signal is the first value, a MUX 124-132 may output its first coefficient, and when the select signal is the second value, the MUX 124-132 may output its second coefficient.

For example, the first MUX 124 has a first coefficient input and a second coefficient input, as well as a first select input 134. When the first select input 134 has a voltage (or current) corresponding to a logical “low” or “0” value, the first MUX 124 may output a first coefficient to the first multiplier 114. When the first select input 134 has a value corresponding to a logical “high” or “1” value, the first MUX 124 may output a second coefficient to the first multiplier 114. The other MUXs 126-132 are similar.

For example, the second MUX 126 has a first coefficient input and a second coefficient input, as well as a second select input 136. When the second select input 136 has a voltage (or current) corresponding to a logical “low” or “0” value, the second MUX 126 may output a first coefficient to the second multiplier 116. When the second select input 136 has a value corresponding to a logical “high” or “1” value, the second MUX 126 may output a second coefficient to the second multiplier 116.

As a further example, the third MUX 128 has a first coefficient input and a second coefficient input, as well as a third select input 138. When the third select input 138 has a voltage (or current) corresponding to a logical “low” or “0” value, the third MUX 128 may output a first coefficient to the third multiplier 118. When the third select input 138 has a value corresponding to a logical “high” or “1” value, the third MUX 128 may output a second coefficient to the third multiplier 118.

As a further example, the fourth MUX 130 has a first coefficient input and a second coefficient input, as well as a fourth select input 140. When the fourth select input 140 has a voltage (or current) corresponding to a logical “low” or “0” value, the fourth MUX 130 may output a first coefficient to the fourth multiplier 120. When the fourth select input 140 has a value corresponding to a logical “high” or “1” value, the fourth MUX 130 may output a second coefficient to the fourth multiplier 120.

As a further example, the fifth MUX 132 has a first coefficient input and a second coefficient input, as well as a fifth select input 142. When the fifth select input 142 has a voltage (or current) corresponding to a logical “low” or “0” value, the fifth MUX 132 may output a first coefficient to the fifth multiplier 122. When the fifth select input 142 has a value corresponding to a logical “high” or “1” value, the fifth MUX 132 may output a second coefficient to the fifth multiplier 122.

In some examples, each MUX 124-132 may receive at its respective select input 134-142 the same select signal at the same time. Thus, in some examples, each MUX 124-132 is outputting its first coefficient at the same time as each other MUX 124-132, and each MUX 124-132 is outputting its second coefficient at the same time as each other MUX 124-132.

In other examples, different select signals may be received at the same or different times, or the same select signal may be received at different times.

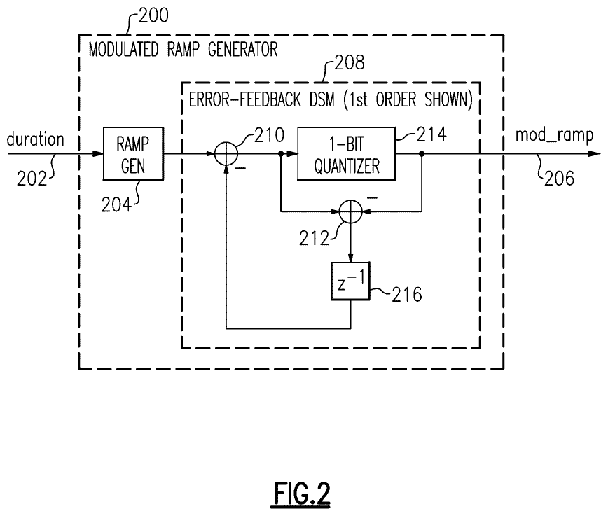

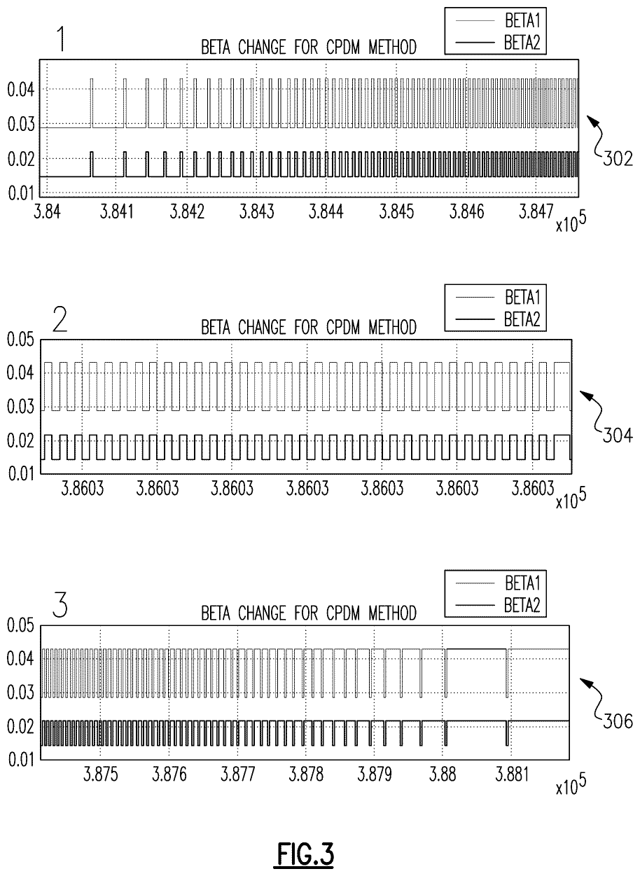

The value of the select signal may, in some examples, be determined using a random or pseudo-random process, for example, as discussed with respect to FIGS. 2 and 3.

Depending on which coefficients are provided to the digital filter 100 by the MUXs 124-132, the response and/or behavior of the digital filter 100 may be controlled.

FIG. 2 illustrates a modulated ramp generator 200 according to an example. The modulated ramp generator 200 includes an input 202, a ramp generator 204, an output 206, and a delta-sigma modulator 208 (“DSM 208”) that includes a first summing node 210, a second summing node 212, a quantizer 214, and a delay 216.

The modulated ramp generator 200 may produce, at the output 206, a signal comprised of high or low voltage values, and/or which alternates between these two values. The output may change in a deterministic manner, as illustrated herein, or may change in a random or pseudorandom manner. In some examples, the output of the modulated ramp generator 200 may be one value (e.g., a low or high value) for a decreasing percentage of time during a transition from the one value to another value (e.g., a high or low value). One possible output pattern for the modulated ramp generator 200 is illustrated in FIG. 3. The output of the modulated ramp generator 200 may be used as an input to the select inputs 134, 136, 138, 140, 142 of FIG. 1: that is, the output of the modulated ramp generator 200 may be used to determine which coefficient a given MUX of the MUXs 124, 126, 128, 130, 132 of FIG. 1 is providing at that MUX's respective output.

The input 202 is coupled to the ramp generator 204. The ramp generator 204 is coupled to the first summing node 210. The first summing node 210 is coupled to the delay 216, the second summing node 212, and the quantizer 214. The quantizer 214 is coupled to the first summing node 210, the second summing node 212, and the output 206. The second summing node 212 is coupled to the delay 216, the first summing node 210 and the quantizer 214.

In some examples, the input is configured to receive an input signal that may operate like an enable signal for the ramp generator 204. That is, the input signal may provide power to the ramp generator 204 and/or cause the ramp generator 204 to generate an output that would be provided to the first summing node 210. The ramp generator 204 may be configured to provide an output voltage (to the first summing node 210) that increases and/or decreases in voltage linearly with time.

In some examples, the first summing node 210 subtracts a signal from the delay 216 from the signal from the ramp generator 204, and then provides the resulting signal to both the quantizer 214 and the second summing node 212. The second summing node 212 then subtracts the output signal from the quantizer 214 from the signal provided by the first summing node 210, and provides the resulting signal to the delay 216. The delay 216 applies a delay to the signal from the second summing node 216 (e.g., a phase shift) and then provides the delayed signal to the first summing node 210.

In some examples, the quantizer 214 is configured to receive the signal from the first summing node 210 and convert that signal from analog-to-digital form (or from continuous to discrete form), and then provide that signal to the output 206.

In some examples, the quantizer 214 selectively outputs either a high value (e.g., logical “high”) or a low value (e.g., logical “low”) to the output 206. The quantizer 214 may therefore provide a signal to both the output 206 and/or second summing node 212 that has only two values, a high voltage and/or a low voltage.

The DSM 208 in FIG. 2 is a first order DSM. However, the DSM 208 may be implemented using a higher order DSM (e.g., second order, third order, fourth order, and so forth). Higher order DSMs may have different responses and zeroes compared to each other and/or the first order DSM. In some examples, the DSM 208 may “shape” noise of the quantization into higher frequencies. For example, in audio application, 20 kHz is a common target, where noise is shaped into frequencies greater than 20 kHz, and therefore inaudible to the vast majority of (if not all) humans.

In FIG. 2, the DSM 208 shapes the coefficient ramp (that is, the signal from the ramp generator 204) to push noise into higher frequency bands. As a result, artifacts in the data stream caused by the coefficient ramp are shaped outside of the desired band. For example, if the desired band is audible frequencies, then the DSM 208 shapes data into bands above 20 KHz.

In some examples, performing the function of shaping the noise requires or involves oversampling the input data (e.g., the coefficient ramp). In such cases, the DSM 208 may sample the coefficient ramp at a rate far higher than coefficient ramp's actual frequency.

FIG. 3 illustrates a set of graphs corresponding to coefficients being provided to a filter, according to an example. For example, the graphs may reflect the amount of time during which a particular coefficient or set of coefficients is provided at the respective outputs of the MUXs 124, 126, 128, 130, 132 of FIG. 1.

FIG. 3 includes a first graph 302, a second graph 304, and a third graph 306. Each graph has two traces, an upper trace corresponding to a first group of coefficients and a lower group corresponding to a second group of coefficients. In some examples, the first group of coefficients may correspond to the coefficients of the first, second, and third MUXs 134, 136, 138 of FIG. 1, and the second group of coefficients may correspond to the coefficients of the fourth and fifth MUXs 140, 142 of FIG. 1. As illustrated, both groups of coefficients change at the same time, as will be described below in greater detail; however, the coefficients could change at different times (as opposed to changing in tandem).

Each trace of the graphs has a low state and a high state. The low state corresponds to a first set of values for the coefficients, and the high state corresponds to a second set of values for the coefficients. For example, as discussed with respect to FIG. 1, each MUX can provide a first coefficient or a second coefficient. When the state of a trace is low, this may correspond to a MUX providing its respective first coefficient, and when the trace is high, this may correspond to a MUX providing its respective second coefficient.

The graphs 302, 304, 306 correspond to three stages in the transition from providing only the respective first coefficient values to providing only the respective second coefficient values. The first graph 302 shows an initial state, where both traces are low, and thus only the first coefficient values are being provided. As time continues, the traces spike indicating that the second coefficient values are being provided. However, as shown in the first graph 302, the period of time during which the traces are high (rather than low) is short. However, as time passes, the amount of time the traces are low decreases and the amount of time the traces are high increases.

The second graph 304 shows a period of time where the traces are high and low for approximately the same amount of time (that is, an equal amount of time is spent providing the first coefficients as is spent providing the second coefficients). The third graph 306 shows a period of time where the traces are high for a larger portion of the time than low, with the third graph 306 ending at a state where the traces are only high.

Thus, the graphs 302, 304, 306 show that the second coefficients can be provided for an increasing percentage of the time during a transition period. Likewise, the reverse is also possible: the first coefficients can also be provided for an increasing percentage of the time during a transition period.

In some examples, the transition illustrated in the graphs 302, 304, 306 may be caused or controlled by the inputs to the select inputs 134, 136, 138, 140, 142 of FIG. 1. Those inputs may be determined by the modulated ramp generator 200 of FIG. 2 in some examples. As explained above, the output of the modulated ramp generator 200 may determine the input to the select inputs 134, 136, 138, 140, 142. Thus, the traces in the graphs 302, 304, 306 may correspond to changes in the output of the modulated ramp generator 200, as that output gradually transitions from being a first value 100% of the time to being a second value 100% of the time (for example, the output goes from being the first value 100% of the time, to the first value 95% of the time, then 80% of the time, then 50% of the time, then 20% of the time, then 5% of the time, then 0% of the time over a predetermined time period). The precise timing of changes between the first and second values depend upon the internal circuitry of the modulated ramp generator 200, as described above.

Examples of the methods and systems discussed herein are not limited in application to the details of construction and the arrangement of components set forth in the description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various controllers and/or a controller may execute various operations discussed above. Using data stored in associated memory and/or storage, the controller also executes one or more instructions stored on one or more non-transitory computer-readable media, which the controller may include and/or be coupled to, that may result in manipulated data. In some examples, the controller may include one or more processors or other types of controllers. In one example, the controller is or includes at least one processor. In another example, the controller performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A system for determining one or more coefficients of a filter, comprising:
a modulated ramp generator including
a ramp generator,
a delta-sigma modulator coupled to the ramp generator and configured to generate a control signal, and
a control output coupled to the delta-sigma modulator and configured to receive the control signal; and
a filter coupled to the control output and configured to receive the control signal from the control output, the filter including
one or more configurable coefficients, values of the configurable coefficients being selected by the control signal,
an input for receiving a filterable signal, and
an output for providing a filtered signal.

2. The system of claim 1 wherein the delta-sigma modulator further includes
a first summing node having an input coupled to an output of the ramp generator;
a quantizer having a quantizer input coupled to an output of first summing node and a quantizer output coupled to the control output;
a second summing node coupled to an output of the first summing node and to the quantizer output; and
a delay line coupled to an output of the second summing node and an input of the first summing node.

3. The system of claim 2 wherein the first summing node is configured to add an output signal of the delay line to an output signal of the ramp generator, and to provide a resulting summed signal to the second summing node and the quantizer.

4. The system of claim 2 wherein the second summing node is configured to add an output signal of the first summing node to an output signal of the quantizer and to provide a resulting summed signal to the delay line.

5. The system of claim 2 wherein the quantizer is a one-bit quantizer.

6. The system of claim 2 wherein the quantizer is configured to provide a control signal to the control output, the control signal being based on an output signal of the first summing node.

7. The system of claim 2 wherein the filter includes a plurality of multipliers and a plurality of multiplexers.

8. The system of claim 7 wherein each multiplexer is configured to receive the control signal.

9. The system of claim 8 wherein each respective multiplexer of the plurality of multiplexers is configured to selectively provide one of a first coefficient and a second coefficient to a respective multiplier of the plurality of multipliers based on the control signal.

10. The system of claim 9 wherein the first coefficient corresponds to a low voltage and the second coefficient corresponds to a high voltage.

11. The system of claim 9 wherein a rate of occurrence over a period of time of the first coefficient decreases over the period of time and a rate of occurrence over a period of time of the second coefficient increases over the period of time.

12. The system of claim 9 wherein, before the period of time, the rate of occurrence of the first coefficient is 100%, and after the first period of time, the rate of occurrence of the first coefficient is 0%.

13. The system of claim 9 wherein, before the period of time, the rate of occurrence of the first coefficient is 0%, and after the first period of time, the rate of occurrence of the first coefficient is 100%.

14. The system of claim 9 wherein, before the period of time, the rate of occurrence of the second coefficient is 100%, and after the first period of time, the rate of occurrence of the second coefficient is 0%.

15. The system of claim 9 wherein, before the period of time, the rate of occurrence of the second coefficient is 0%, and after the first period of time, the rate of occurrence of the second coefficient is 100%.

16. The system of claim 2 wherein the filter includes a multiplier and a multiplexer, the multiplexer being configured to selectively provide one of a first coefficient and a second coefficient as a selected coefficient to the multiplier based on the control signal, wherein the multiplier multiplies the selected coefficient with a target signal and generates a multiplied signal based on the selected signal and the target signal.

17. A method of operating a filter, comprising:
providing a first coefficient to a configurable filter for a first period of time;
providing the first coefficient and a second coefficient to the configurable filter for a second period of time by alternating between the first coefficient and the second coefficient such that at a beginning of the second period of time the first coefficient is provided for a majority of the time, and at an end of the second period of time the second coefficient is provided for a majority of the time; and
providing the second coefficient to the configurable filter for a third period of time.

18. The method of claim 17 wherein the first coefficient is 0 and the second coefficient is 1.

19. The method of claim 17 further comprising using a ramp generator and a delta-sigma modulator (DSM) to provide a control signal to the configurable filter, wherein a state of the control signal determines whether the first coefficient is provided to the configurable filter or the second coefficient is provided to the configurable filter.

20. The method of claim 17 wherein the second coefficient is not provided during the first period of time, and the first coefficient is not provided during the second period of time.
